(19) United States
(12) Patent Application Publication
(10) Pub. No.: US 2024/0178635 A1
(43) Pub. Date: May 30, 2024

(54) CONTROL METHOD AND CONTROL DEVICE OF WAVELENGTH TUNABLE LASER DEVICE, AND NON-TRANSITORY STORAGE MEDIUM STORING CONTROL PROGRAM OF WAVELENGTH TUNABLE LASER DEVICE

(71) Applicant: Sumitomo Electric Industries, Ltd., Osaka (JP)

(72) Inventor: Tsutomu ISHIKAWA, Osaka-shi (JP)

(73) Assignee: Sumitomo Electric Industries, Ltd., Osaka (JP)

(21) Appl. No.: 18/499,391

(22) Filed: Nov. 1, 2023

(30) Foreign Application Priority Data
Nov. 30, 2022 (JP) 2022-192107

(51) Int. Cl. H01S 5/06; G02F 1/01; H01S 5/0625; H01S 5/10; H01S 5/343

(52) U.S. Cl. CPC H01S 5/0612; G02F 1/0147; H01S 5/06255; H01S 5/1007; H01S 5/101; H01S 5/3434; H01S 5/34386

(57) ABSTRACT

A method of controlling a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which gains of the plurality of semiconductor elements reach peaks differ from one another. The method includes, selecting a first optical waveguide configured to transmit light from among the plurality of first optical waveguides, and causing light to be emitted from a first semiconductor element that is a semiconductor element optically coupled to the selected first optical waveguide among the plurality of semiconductor elements.

### CROSS REFERENCE TO RELATED APPLICATIONS

This application claims priority based on Japanese Patent Application No. 2022-192107 filed on Nov. 30, 2022, and the entire contents of the Japanese patent application are incorporated herein by reference.

### TECHNICAL FIELD

The present disclosure relates to a control method and a control device of a wavelength tunable laser device, and a non-transitory storage medium storing a control program of the wavelength tunable laser device.

### BACKGROUND

A wavelength tunable laser device is known (for example, Naoki Kobayashi et al. “Silicon Photonic Hybrid Ring-Filter External Cavity Wavelength Tunable Lasers” Journal of Lightwave Technology, Vol. 33, No. 6, p. 1241, Mar. 15 2015). The wavelength tunable laser device includes a semiconductor element having an optical gain, a ring resonator, and the like. An oscillation wavelength of light is changed by adjusting a resonant wavelength of the ring resonator.

### SUMMARY

A method of controlling a wavelength tunable laser device according to the present disclosure is a control method of a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which the optical gains of the plurality of semiconductor elements reach peaks differ from one another. The method includes selecting a first optical waveguide configured to transmit light from among the plurality of first optical waveguides, and causing light to be emitted from a first semiconductor element that is a semiconductor element optically coupled to the selected first optical waveguide among the plurality of semiconductor elements.

A non-transitory storage medium according to the present disclosure stores a control program executable by a computer for controlling a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which the optical gains of the plurality of semiconductor elements reach peaks differ from one another. The control program causes a computer to function as a selection controller configured to select a first optical waveguide configured to transmit light from among the plurality of first optical waveguides and an emission controller configured to cause light to be emitted from a semiconductor element optically coupled to the selected first optical waveguide among the plurality of semiconductor elements.

A control device according to the present disclosure is configured to control a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which the optical gains of the plurality of semiconductor elements reach peaks differ from one another. The control device includes a selection controller configured to select a first optical waveguide configured to transmit light from among the plurality of first optical waveguides, and an emission controller configured to cause light to be emitted from a semiconductor element optically coupled to the selected first optical waveguide among the plurality of semiconductor elements.

### BRIEF DESCRIPTION OF THE DRAWINGS

FIG. 1 is a plan view of a wavelength tunable laser device according to an embodiment.

FIG. 2A is a cross-sectional view taken along line A-A in FIG. 1.

FIG. 2B is a cross-sectional view taken along line B-B in FIG. 1.

FIG. 3A is a diagram illustrating an optical gain of a semiconductor element.

FIG. 3B is a diagram illustrating a light transmittance of an optical waveguide.

FIG. 4 is a block diagram of a control device.

FIG. 5 is a block diagram of a hardware configuration of the controller.

FIG. 6 is a flowchart of a process executed by the control device.

FIG. 7 is a diagram illustrating the optical gain of the semiconductor element.

### DETAILED DESCRIPTION

By reducing a wavelength dependence of an optical gain of a semiconductor element, a tunable range of wavelength can be expanded. However, reducing the wavelength dependence in a semiconductor element using a single gain region increases a threshold current density of the semiconductor element. This increases a spectral line width and also increases an electric power consumption. Therefore, an object of the present disclosure is to provide a control method and a control device of a wavelength tunable laser device having a narrow spectral line width and allowing an electric power consumption to be reduced, and a non-transitory storage medium storing a control program of the wavelength tunable laser device.

### Description of Embodiments of Present Disclosure

First, the contents of embodiments according to the present disclosure will be listed and described.
(1) According to one aspect of the present disclosure, a method of controlling a wavelength tunable laser device is a method of controlling a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which the optical gains of the plurality of semiconductor elements reach peaks differ from one another. The method includes selecting a first optical waveguide configured to transmit light from among the plurality of first optical waveguides, and causing light to be emitted from a first semiconductor element that is a semiconductor element optically coupled to the selected first optical waveguide among the plurality of semiconductor elements. An optical waveguide configured to transmit light is selected. Light is emitted from the semiconductor element optically coupled to the selected optical waveguide. A wavelength of light can be changed by switching between the optical waveguides and between the semiconductor elements. Each of the semiconductor elements is driven in a high gain band. Increases in threshold current density and electric power consumption are suppressed. A spectral line width is narrowed.
(2) In the above (1), a heater may be provided over one of two of the first optical waveguides. The selecting may include selecting one of the two first optical waveguides by controlling an electric power to be input to the heater. By changing the electric power, a transmittance of one of the two first optical waveguides is increased and a transmittance of the other one is decreased. The emitted light can be propagated through one of the first optical waveguides.
(3) In the above (2), the selecting may include selecting one of the two first optical waveguides by setting an electric power to be input to the heater to a first value, and selecting the other one of the two first optical waveguides by setting the electric power to a second value. The two optical waveguides can be switched by controlling the electric power to be input to the heater.
(4) In any one of the above (1) to (3), the substrate may include a second optical waveguide optically coupled to the plurality of first optical waveguides. The second optical waveguide may be branched into two. One of the first optical waveguides may be optically coupled to one of the two branched second optical waveguides, and another one of the first optical waveguides may be optically coupled to the other one of the two branched second optical waveguides. The method may include selecting a second optical waveguide configured to transmit light from among the two branched second optical waveguides. In the selecting the second optical waveguide configured to transmit light, a second optical waveguide optically coupled to the selected first optical waveguide may be selected. The emitted light from the semiconductor element can be propagated through the first optical waveguide and the second optical waveguide.
(5) In the above (4), the wavelength tunable laser device may include a plurality of ring resonators optically coupled to the second optical waveguide. The method may include controlling resonant wavelengths of the plurality of ring resonators. Ring resonators can be used to control the wavelength of light.
(6) In any one of the above (1) to (5), the method may include increasing a light absorptivity of a second semiconductor element that is a semiconductor element other than the first semiconductor element among the plurality of semiconductor elements to be higher than the light absorptivity before the causing the light to be emitted. Light is emitted from the first semiconductor element. Since the second semiconductor element absorbs light, unnecessary reflected light can be reduced.
(7) In the above (6), the causing the light to be emitted from the first semiconductor element may include applying a forward bias voltage to the first semiconductor element. The increasing the light absorptivity of the second semiconductor element may include applying a reverse bias voltage to the second semiconductor element. Light is emitted from the first semiconductor element. Since the second semiconductor element absorbs light, unnecessary reflected light can be reduced.
(8) In the above (6) or (7), the increasing the light absorptivity of the second semiconductor element may include detecting a reverse bias current flowing through the second semiconductor element, and controlling the reverse bias current to a minimum value. Since the second semiconductor element absorbs light, unnecessary reflected light can be reduced. The singleness of wavelength of the emitted light is improved.
(9) A non-transitory storage medium stores a control program executable by a computer for controlling a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which the optical gains of the plurality of semiconductor elements reach peaks differ from one another. The control program causes a computer to function as a selection controller configured to select a first optical waveguide configured to transmit light from among the plurality of first optical waveguides and an emission controller configured to cause light to be emitted from a semiconductor element optically coupled to the selected first optical waveguide among the plurality of semiconductor elements. An optical waveguide configured to transmit light is selected. Light is emitted from a semiconductor element optically coupled to the selected optical waveguide. The wavelength of light can be changed by switching between the optical waveguides and between the semiconductor elements. Each of the semiconductor elements is driven in a high gain band. Increases in threshold current density and electric power consumption are suppressed. The spectral line width is narrowed.
(10) A control device is configured to control a wavelength tunable laser device including a substrate and a plurality of semiconductor elements. A plurality of first optical waveguides are provided in the substrate. The plurality of semiconductor elements are formed of a III-V group compound semiconductor, have optical gains, and are optically coupled to the plurality of first optical waveguides of the substrate. Wavelengths with which the optical gains of the plurality of semiconductor elements reach peaks differ from one another. The control device includes a selection controller configured to select a first optical waveguide configured to transmit light from among the plurality of first optical waveguides, and an emission controller configured to cause light to be emitted from a semiconductor element optically coupled to the selected first optical waveguide among the plurality of semiconductor elements. An optical waveguide configured to transmit light is selected. Light is emitted from a semiconductor element optically coupled to the selected optical waveguide. The wavelength of light can be changed by switching between the optical waveguides and between the semiconductor elements. Each of the semiconductor elements is driven in a high gain band. Increases in threshold current density and electric power consumption are suppressed. The spectral line width is narrowed.

### Details of Embodiments of Present Disclosure

Specific examples of a control method, a control program, and a control device of a wavelength tunable laser device according to an embodiment of the present disclosure will be described below with reference to the drawings. The present disclosure is not limited to these examples, and is defined by the scope of the claims, and is intended to include all modifications within the meaning and scope equivalent to the scope of the claims.

### Embodiment

### (Wavelength Tunable Laser Device)

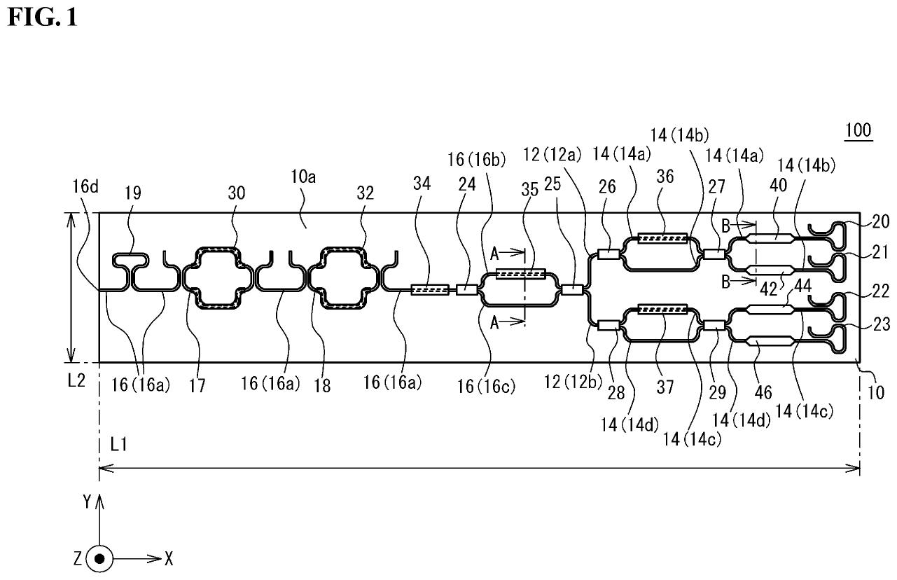

FIG. 1 is a plan view of a wavelength tunable laser device 100 according to an embodiment. Wavelength tunable laser device 100 is a hybrid type optical device including a substrate 10 and a plurality of semiconductor elements 40. Substrate 10 includes a surface 10a parallel to an XY-plane. The plurality of semiconductor elements 40 are bonded on surface 10a of substrate 10.

Substrate 10 has a rectangular planar shape. Two sides of substrate 10 extend parallel to an X-axis direction. The other two sides extend parallel to a Y-axis direction. A Z-axis direction is a normal direction of the XY-plane and is a stacking direction of layers. The X-axis direction, the Y-axis direction, and the Z-axis direction are orthogonal to one another. Substrate 10 has a length L1 of, for example, 5 mm in the X-axis direction. Substrate 10 has a length L2 of, for example, 2.5 mm in the Y-axis direction.

Substrate 10 is a silicon on insulator (SOI) substrate. An optical waveguide 12, an optical waveguide 14 (first optical waveguide), an optical waveguide 16, a ring resonator 17, a ring resonator 18, and loop mirrors 19, 20, 21, 22, and 23 are provided in surface 10a of substrate 10.

Optical waveguide 12 and optical waveguide 16 correspond to a second optical waveguide. Optical waveguide 16 includes optical waveguides 16a and 16b and 16c. One end portion 16d of optical waveguide 16a is located at an end portion of substrate 10 and functions as a light emitting port. Optical waveguide 16a includes a straight portion and a curved portion and extends from the end portion of substrate 10 to a coupler 24.

Loop mirror 19 (second reflector) and ring resonators 17 and 18 are provided in optical waveguide 16a. Between the end portion of substrate 10 and coupler 24, loop mirror 19, ring resonator 17, and ring resonator 18 are arranged in this order. Optical waveguide 16a is curved into a loop shape to form loop mirror 19.

Ring resonator 17 and ring resonator 18 are optically coupled to optical waveguide 16a. Ring resonator 17 has a diameter different from a diameter of ring resonator 18. Ring resonator 17 has a free spectral range (FSR, interval between two adjacent resonant wavelengths) of, for example, 2.7 nm. Ring resonator 18 has an FSR of, for example, 3.0 nm. Ring resonator 17 is provided with a heater 30. Ring resonator 18 is provided with a heater 32.

Optical waveguide 16 is branched into two at coupler 24. One end portion of optical waveguide 16a is optically coupled to one end portion of coupler 24. One end portion of each of optical waveguides 16b and 16c is optically coupled to the other end portion of coupler 24. Optical waveguide 16b is provided with a heater 35. Optical waveguide 16c is provided with no heater. The other end portions of optical waveguide 16b and 16c are optically coupled to one end portion of a coupler 25.

Optical waveguide 12 includes optical waveguides 12a and 12b. One end portion of each of optical waveguides 12a and 12b is optically coupled to the other end portion of coupler 25. The other end portion of optical waveguide 12a is optically coupled to a coupler 26. The other end portion of optical waveguide 12b is optically coupled to a coupler 28.

Optical waveguide 14 includes optical waveguides 14a, 14b, 14c and 14d. One end portion of each of optical waveguides 14a and 14b is optically coupled to coupler 26. A coupler 27 is provided in the middle of optical waveguides 14a and 14b. That is, optical waveguides 14a and 14b are branched at coupler 26, extend to one end portion of coupler 27, and are branched at the other end portion of coupler 27. A heater 36 is provided over a portion of optical waveguide 14a between coupler 26 and coupler 27. Optical waveguide 14b is provided with no heater.

Loop mirror 20 is provided in an end portion of optical waveguide 14a opposite to coupler 26. Loop mirror 21 is provided in an end portion of optical waveguide 14b opposite to coupler 26.

Semiconductor element 40 is bonded on a portion of optical waveguide 14a between coupler 27 and loop mirror 20. A semiconductor element 42 is bonded on a portion of optical waveguide 14b between coupler 27 and loop mirror 21.

Optical waveguides 14c and 14d are optically coupled to coupler 28. A coupler 29 is provided in the middle of optical waveguides 14c and 14d. A heater 37 is provided over a portion of optical waveguide 14c between coupler 28 and coupler 29. Optical waveguide 14d is provided with no heater.

Loop mirror 22 is provided in an end portion of optical waveguide 14c opposite to coupler 28. Loop mirror 23 is provided in an end portion of optical waveguide 14d opposite to coupler 28.

A semiconductor element 44 is bonded on a portion of optical waveguide 14c between coupler 29 and loop mirror 22. A semiconductor element 46 is bonded on a portion of optical waveguide 14d between coupler 29 and loop mirror 23.

Each of semiconductor elements 40, 42, 44 and 46 includes tapered portions at both ends. Each of tapered portions has a tapered shape along the optical waveguide. Loop mirror 19 has a light reflectance of, for example, 30%. Each of loop mirrors 20, 21, 22 and 23 is a first reflector. The optical reflectances of loop mirrors 20, 21, 22, and 23 are higher than the reflectance of loop mirror 19, for example, 90% or more, and may be close to 100%. Couplers 24, 25, 26, 27, 28, and 29 may be, for example, multi-mode interferences (MMIs) or directional couplers.

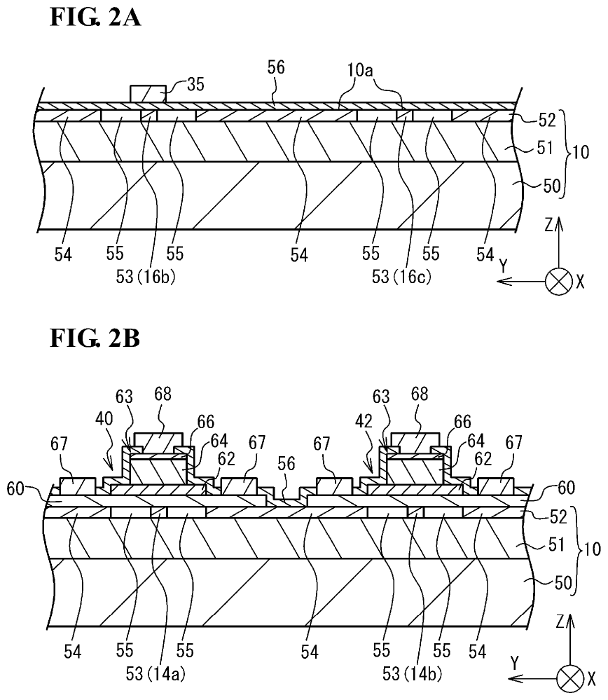

FIG. 2A is a cross-sectional view taken along line A-A in FIG. 1 and shows a cross-sectional view including two optical waveguides 16b and 16c and heater 35. Substrate 10 is an SOI substrate and includes a substrate 50, a box layer 51, and a silicon (Si) layer 52. Box layer 51 is stacked on a surface of substrate 50. Si layer 52 is stacked on a surface of box layer 51 opposite to substrate 50.

Si layer 52 includes a waveguide core 53, a terrace 54 and a groove 55. The surface of terrace 54 is a plane of Si. Waveguide core 53 is spaced apart from terrace 54. Groove 55 is provided between terrace 54 and waveguide core 53. The surfaces of waveguide core 53 and terrace 54 form plane 10a of substrate 10. Groove 55 is recessed from surface 10a, and may penetrate Si layer 52 in the Z-axis direction or may extend to the middle of Si layer 52 in the Z-axis direction.

Substrate 50 is formed of, for example, Si. Box layer 51 is formed of, for example, silicon oxide (SiO₂). Si layer 52 is formed of Si having a thickness of 0.22 μm, for example. Waveguide core 53 has a width of, for example, 0.42 μm.

One of two waveguide cores 53 in FIG. 2A functions as optical waveguide 16b. The other one of waveguide cores 53 functions as optical waveguide 16c. Waveguide core 53 forms the optical waveguides, the loop mirrors and the ring resonators of wavelength tunable laser device 100.

As shown in FIG. 2A, a top surface of Si layer 52 is covered with an insulating film 56. Heater 35 is provided on a top surface of insulating film 56 and over optical waveguide 16b. Insulating film 56 is formed of an insulator such as silicon nitride (SiN). Heater 35 is formed of a metal such as platinum (Pt).

FIG. 2B is a cross-sectional view taken along line B-B in FIG. 1 and shows a cross-section including semiconductor elements 40 and 42. Semiconductor element 40 is bonded on optical waveguide 14a. Semiconductor element 42 is bonded on optical waveguide 14b.

Semiconductor element 40 includes a cladding layer 60 (first semiconductor layer), an active layer 62, a cladding layer 64, and a contact layer 66 (cladding layer 64 and contact layer 66 are second semiconductor layers). Cladding layer 60 is in contact with Si layer 52 of substrate 10 and disposed over waveguide core 53, groove 55, and terrace 54. Active layer 62, cladding layer 64, and contact layer 66 are stacked in this order on cladding layer 60. Each mesa 63 includes active layer 62, cladding layer 64 and contact layer 66 and is disposed over waveguide core 53.

Insulating film 56 covers a top surface of cladding layer 60 and side and top surfaces of each mesa 63. In insulating film 56, openings are formed over cladding layer 60 and over each mesa 63. An electrode 67 is provided in the opening over cladding layer 60 and is in contact with the top surface of cladding layer 60. An electrode 68 is provided in the opening over each mesa 63 and is in contact with the top surface of contact layer 66.

Cladding layer 60 is formed of, for example, n-type (first conductivity type) indium phosphide (InP). Active layer 62 includes a plurality of well layers and a plurality of barrier layers. The plurality of well layers and the plurality of barrier layers are alternately stacked to form a multi quantum well (MQW) structure. The well layers and the barrier layers are formed of gallium indium arsenide phosphide (GaInAsP), for example. Cladding layer 64 is formed of, for example, p-type (second conductivity type) InP. Contact layer 66 is formed of, for example, p-type indium gallium arsenide (InGaAs). The semiconductor layers of the semiconductor elements may be formed of a III-V group compound semiconductor other than semiconductors described above.

Electrode 67 is formed of a metal such as a stacked body of gold, germanium, and nickel (Au/Ge/Ni). Electrode 68 is formed of a metal such as a stacked body of titanium, platinum, and gold (Ti/Pt/Au).

Semiconductor elements 42, 44 and 46 have the same configuration as semiconductor element 40. As shown in FIG. 2B, semiconductor element 40 is spaced apart from semiconductor element 42. The semiconductor layers and the electrodes of semiconductor element 40 are not in contact with the semiconductor layers and the electrodes of semiconductor element 42. Four semiconductor elements 40, 42, 44 and 46 are spaced apart and electrically isolated from one another. The four semiconductor elements are controlled independently of one another.

The four semiconductor elements have optical gains. When forward bias voltages are applied to the semiconductor elements, the semiconductor elements generate light. The application of the forward bias voltage means that a positive voltage is applied to electrode 68 and a negative voltage is applied to electrode 67. Current flows between contact layer 66 and cladding layer 60, carriers are injected into active layer 62, and light is generated. The semiconductor elements and the optical waveguides are optically coupled to each other by evanescent light coupling, and light is transferred between them.

When reverse bias voltages are applied to the semiconductor elements, the semiconductor elements easily absorb light. The application of the reverse bias voltage means that a negative voltage is applied to electrode 68 and a positive voltage is applied to electrode 67. Active layer 62 absorbs light and generates carriers. The carriers cause a current flow.

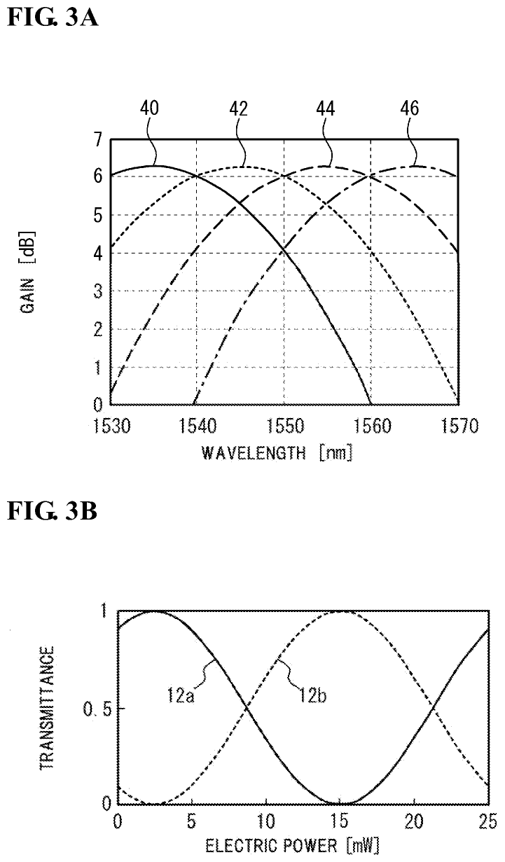

FIG. 3A is a diagram illustrating optical gains of the semiconductor elements. A horizontal axis represents a wavelength. A vertical axis represents the gain (optical gain). The semiconductor elements have a length of 500 μm in the X-axis direction. A current of 100 mA flows through the semiconductor elements.

The gain of semiconductor element 40 is represented by a solid line in FIG. 3A and has a peak around a wavelength of 1535 nm. The gain of semiconductor element 42 is represented by a dotted line and has a peak around a wavelength of 1545 nm. The gain of semiconductor element 44 is represented by a dashed line and has a peak around a wavelength of 1555 nm. The gain of semiconductor element 46 is represented by a one-dot chain line, and has a peak around a wavelength of 1565 nm. The difference among the wavelengths with which the optical gains of the plurality of semiconductor elements reach the peaks is 10 nm or more, for example. The difference in peak wavelength is caused by a difference in composition of each active layer 62. The peak values of the gains are higher than 6 dB and are of equal magnitude in each of semiconductor elements.

The four semiconductor elements are used as light-emitting elements in wavelength bands in which the respective semiconductor elements have high gains. For example, semiconductor element 40 is used as a light-emitting element in a range from about 1530 nm to about 1540 nm. Semiconductor element 42 is used as a light-emitting element in a range from about 1540 nm to about 1550 nm. Semiconductor element 44 is used as a light-emitting element in a range from about 1550 nm to about 1560 nm. Semiconductor element 46 is used as a light-emitting element in a range from about 1560 nm to about 1570 nm. In each of the bands, a forward bias voltage is applied to a semiconductor element used as a light-emitting element among the semiconductor elements. Reverse bias voltages are applied to the other three semiconductor elements that are not used.

FIG. 3B is a diagram illustrating light transmittances of optical waveguides. A horizontal axis represents an electric power to be input to a heater. Heater 35 provided in optical waveguide 16b is used as an example. Heater 35 has a length of 500 μm. A vertical axis represents the light transmittance, and here, a ratio of light emitted to optical waveguide 12a or 12b to light incident on coupler 24 is defined as the light transmittance to optical waveguide 12a or 12b, respectively. A solid line represents the light transmittance to optical waveguide 12a. A dotted line represents the light transmittance to optical waveguide 12b.

When current flows through heater 35, heater 35 generates heat. A refractive index of the optical waveguide changes with a temperature thereof. The change in index of refraction facilitates light propagation into one of two optical waveguides 16b and 16c. As shown in FIG. 3B, the light transmittance periodically changes like a sine curve, for example, in response to a change in electric power. The transmittance to optical waveguide 12a and the transmittance to optical waveguide 12b are in opposite phases to each other. When the electric power is from 0 to 2.5 mW, the transmittance to optical waveguide 12a increases. The transmittance to optical waveguide 12b decreases. When the electric power is 2.5 mW, the transmittance to optical waveguide 12a is 1. The transmittance to optical waveguide 12b is zero. In an electric power of 2.5 mW to 15 mW, the transmittance to optical waveguide 12a decreases. The transmittance to optical waveguide 12b increases. When the electric power is 15 mW, the transmittance to optical waveguide 12a is zero. The transmittance to optical waveguide 12b is one.

When the electric power is 2.5 mW, the transmittance to optical waveguide 12a maximized, and the transmittance to optical waveguide 12b is minimized. When the electric power is 15 mW, the transmittance to optical waveguide 12b is maximized, and the transmittance to optical waveguide 12a is minimized. By controlling the electric power, it is possible to select an optical waveguide configured to transmit light from among two optical waveguides 12a and 12b. Heater 35 functions as a selector that selects an optical waveguide configured to transmit light from among optical waveguides 12a and 12b.

The same relationship as in FIG. 3B is established between the electric power to be input to heater 36 and the light transmittance to optical waveguide 14a and the light transmittance to optical waveguide 14b. Heater 36 functions as a selector that selects an optical waveguide configured to transmit light from among two optical waveguides 14a and 14b. The same relationship as shown in FIG. 3B is established between the electric power to be input to heater 37 and the light transmittance to optical waveguide 14c and the light transmittance to optical waveguide 14d. Heater 37 functions as a selector that selects an optical waveguide configured to transmit light from among two optical waveguides 14c and 14d.

### (Control Device)

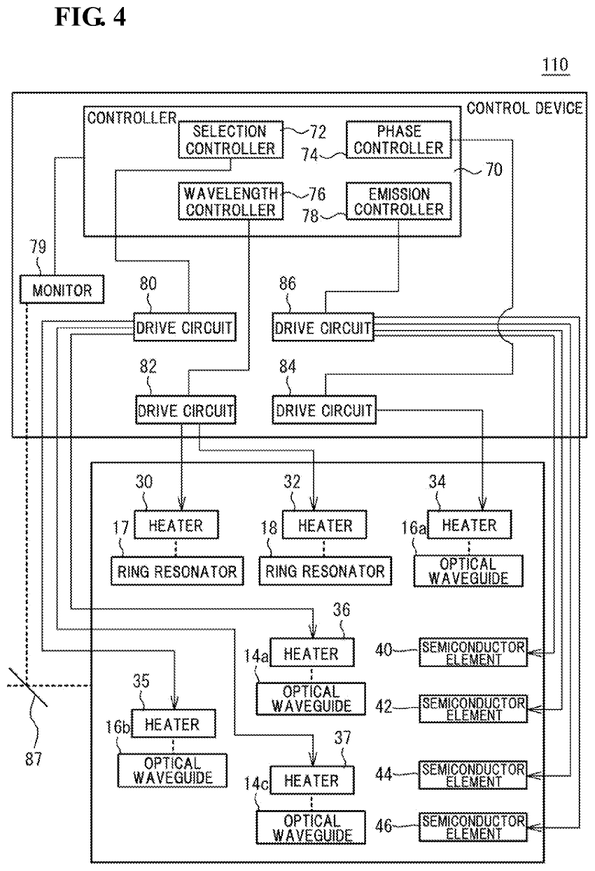

FIG. 4 is a block diagram of a control device 110. Control device 110 is configured to control wavelength tunable laser device 100. Control device 110 includes a controller 70, a monitor 79, and drive circuits 80, 82, 84, and 86.

A half mirror 87 faces a light emitting port of wavelength tunable laser device 100. The light emitted from wavelength tunable laser device 100 is partially transmitted through half mirror 87, and is partially reflected on half mirror 87 to enter monitor 79. Monitor 79 is configured to measure a wavelength and an intensity of the light.

Each of the drive circuits includes an electric power supply and is configured to output and stop an electric power. Drive circuit 80 is configured to control the electric power to be input to each of heaters 35, 36 and 37. Drive circuit 82 is configured to control the electric power to be input to each of heaters 30 and 32. Drive circuit 84 is configured to control the electric power to be input to a heater 34. Drive circuit 86 is configured to control a voltage applied to each of semiconductor elements 40, 42, 44, and 46.

Controller 70 includes, for example, a computer, and is connected to monitor 79 and the drive circuits. Controller 70 acquires a wavelength and an intensity of light detected by monitor 79.

Controller 70 functions as a selection controller 72, a phase controller 74, a wavelength controller 76, and an emission controller 78. Selection controller 72 is configured to control drive circuit 80 to adjust the electric power to be input to each of heaters 35, 36, and 37, and selects an optical waveguide serving as an optical path. Phase controller 74 is configured to control drive circuit 84 to control the electric power to be input to heater 34, and controls a phase of light.

Wavelength controller 76 is configured to control drive circuit 82 to adjust the electric power to be input to heaters 30 and 32. Drive circuit 82 is configured to adjust the electric power to adjust resonant wavelengths of ring resonators 17 and 18, thereby controlling an oscillation wavelength of light.

Emission controller 78 is configured to control drive circuit 86 to control voltages applied to semiconductor elements 40, 42, 44, and 46. Emission controller 78 is configured to cause the semiconductor elements to emit light by applying forward bias voltages to the semiconductor elements. Emission controller 78 applies reverse bias voltages to the semiconductor elements so that light is not emitted and the light absorptivities of the semiconductor elements are increased. Emission controller 78 measures currents flowing through the semiconductor elements to which the reverse bias voltages are applied.

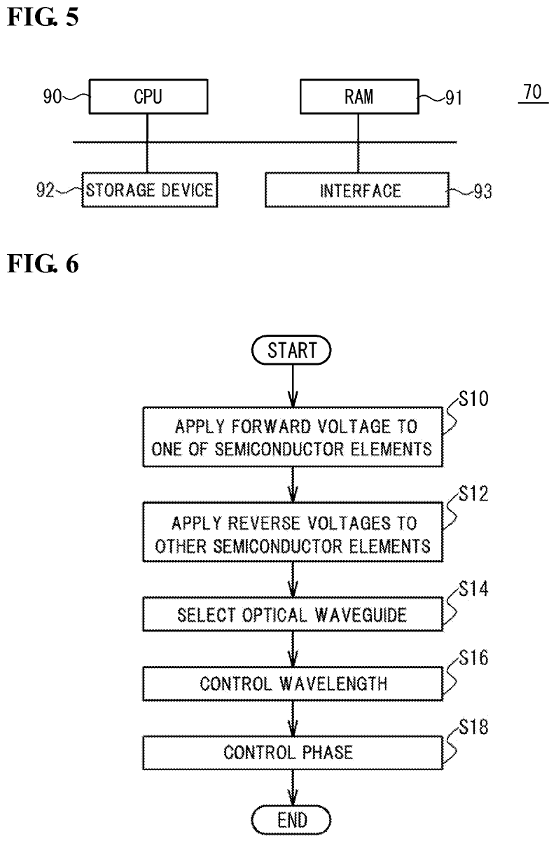

FIG. 5 is a block diagram of a hardware configuration of controller 70. As shown in FIG. 5, controller 70 includes a central processing unit (CPU) 90, a random access memory (RAM) 91, a storage device 92, and an interface 93. CPU 90, RAM 91, storage device 92, and interface 93 are connected to each other via a bus or the like. RAM 91 is a volatile memory that temporarily stores programs, data, and the like. Storage device 92 is a solid state drive (SSD) such as a read only memory (ROM) and a flash memory, a hard disk drive (HDD), and the like. Storage device 92 stores a data table to be described later, a processing program, and the like.

When CPU 90 executes a program stored in RAM 91, selection controller 72, phase controller 74, wavelength controller 76, and emission controller 78 shown in FIG. 4 are implemented in controller 70. Each of controllers included in controller 70 may be a hardware such as a circuit.

FIG. 6 is a flow chart of a process executed by control device 110. Before emitting a desired wavelength, control device 110 reads data of a channel corresponding to the wavelength from a data table. The data table includes data serving as initial values for a plurality of voltages applied to a plurality of semiconductor elements and a plurality of electric powers to be input to a plurality of heaters. Emission controller 78 applies a forward bias voltage to one of the four semiconductor elements (step S10), and applies reverse bias voltages to the other semiconductor elements (step S12). Selection controller 72 inputs electric powers of the initial values to heaters 35, 36, and 37, and selects an optical waveguide serving as an optical path. Emission controller 78 detects currents (reverse bias currents) flowing through the semiconductor elements to which the reverse bias voltages are applied. Selection controller 72 adjusts the electric powers to be input to heaters 35, 36, and 37 so that the currents detected by emission controller 78 are minimized (step S14). When the reverse bias currents take minimum values, the intensities of light propagating through the optical waveguides coupled to the three semiconductor elements take minimum values.

Wavelength controller 76 inputs electric powers of the initial values to heaters 30 and 32 to set a wavelengths of light (step S16). Phase controller 74 inputs electric powers of the initial value to heater 34 to set a phase of light. Accordingly, light is emitted from the light emitting port of wavelength tunable laser device 100. The emitted light has a wavelength close to the desired wavelength. Monitor 79 detects the wavelength and intensity of the emitted light. Phase controller 74 adjusts the electric power to be input to heater 34 so as to maximize the intensity of the detected emitted light (step S18). When the intensity of the emitted light is maximized and the wavelength of the emitted light matches the desired wavelength, control device 110 completes the process shown in FIG. 6.

When the wavelength of the emitted light is different from the desired wavelengths, wavelength controller 76 readjusts the electric powers to be input to heaters 30 and 32 so that the wavelength of the emitted light approaches the desired wavelength (step S16). Selection controller 72 readjusts the electric powers to be input to heaters 35, 36, and 37 so as to minimize the currents flowing through the optical semiconductor elements to which the reverse bias voltages are applied (step S14). Wavelength controller 76 readjusts the electric powers to be input to heaters 30 and 32 so that the wavelength of the emitted light approaches the desired wavelength (step S16). Phase controller 74 readjusts the electric power to be input to heater 34 so as to maximize the intensity of the emitted light (step S18). Control device 110 repeats steps S14 to S18 shown in FIG. 6 until the wavelength of the emitted light matches the desired wavelength. Steps S10 to S18 may be performed in the order shown in FIG. 6 or in a different order.

In each of steps S14, S16, S16, a dithering technique may be applied. The application of the dithering technique is as follows. In step S14, selection controller 72 periodically sweeps the electric power to each of heaters 35, 36 and 37 within predetermined electric power ranges. Emission controller 78 detects currents that periodically change with the electric power sweep. Thus, the electric powers at which the currents are minimized are determined. In step S16, wavelength controller 76 periodically sweeps the electric power to each of heaters 30 and 32 within predetermined electric power ranges. Monitor 79 detects a wavelength that periodically changes with the electric power sweep. This determines the electric power at which the desired wavelength is obtained. In step S18, phase controller 74 periodically sweeps the electric power to be input to heater 34. Monitor 79 monitors the intensity of the emitted light that periodically changes. This optimally adjusts the phase.

An example of control of wavelength tunable laser device 100 will be described. Tables 1 to 3 are data tables used for control, and are stored in storage device 92 of controller 70. Table 1 illustrates the states of the semiconductor elements. Tables 2 and 3 illustrate the states of the heaters. Table 2 summarizes the states of heaters 35, 36 and 37 for optical waveguide selection. Table 3 summarizes the states of heaters 30, 32, and 34.

TABLE 1

| | Semiconductor | Semiconductor | Semiconductor | Semiconductor |
|---|---|---|---|---|
| Ch | element 40 | element 42 | element 44 | element 46 |
| 1 | Forward bias | Reverse bias | | |
| 2 | (100 mA) | (−1 V) | | |
| • | | | | |
| • | | | | |
| • | | | | |
| 25 | | | | |
| 26 | Reverse bias | Forward bias | Reverse bias | |
| 27 | (−1 V) | (100 mA) | (−1 V) | |
| • | | | | |
| • | | | | |
| • | | | | |
| 50 | | | | |
| 51 | Reverse bias | | Forward bias | Reverse bias |
| 52 | (−1 V) | | (100 mA) | (−1 V) |
| • | | | | |
| • | | | | |
| • | | | | |
| 75 | | | | |
| 76 | Reverse bias | | | Forward bias |
| 77 | (−1 V) | | | (100 mA) |
| • | | | | |
| • | | | | |
| • | | | | |
| 100 | | | | |

TABLE 2

| Ch | Heater 35 | Heater 36 | Heater 37 |
|---|---|---|---|
| 1 | 2.5 mW | 2.5 mW | Off |
| 2 | (Optical waveguide | (Optical waveguide | |
| • | 12a) | 14a) | |
| • | | | |
| • | | | |
| 25 | | | |
| 26 | 2.5 mW | 15 mW | Off |
| 27 | (Optical waveguide | (Optical waveguide | |
| • | 12a) | 14b) | |
| • | | | |
| • | | | |
| 50 | | | |
| 51 | 15 mW | Off | 2.5 mW |
| 52 | (Optical waveguide | | (Optical waveguide |
| • | 12b) | | 14c) |
| • | | | |
| • | | | |
| 75 | | | |
| 76 | 15 mW | Off | 15 mW |
| 77 | (Optical waveguide | | (Optical waveguide |
| • | 12b) | | 14d) |
| • | | | |
| • | | | |
| 100 | | | |

TABLE 3

| Ch | Heater 30 | Heater 32 | | Heater 34 | | Wavelength(nm) |
|---|---|---|---|---|---|---|
| 1 | 13.64 mW | 2.12 | mW | 0.59 | mW | 1528.773 |
| 2 | 17.85 mW | 6.21 | mW | 13.13 | mW | 1529.163 |

•
•
•

| | | | | | | |
|---|---|---|---|---|---|---|
| 25 | 15.17 mW | 3.57 | mW | 5.69 | mW | 1538.186 |
| 26 | 19.58 mW | 7.73 | mW | 3.08 | mW | 1538.581 |
| 27 | 23.83 mW | 11.86 | mW | 0.47 | mW | 1538.976 |

•
•
•

| | | | | | | |
|---|---|---|---|---|---|---|
| 50 | 20.08 mW | 8.52 | mW | 13.92 | mW | 1548.115 |
| 51 | 24.57 mW | 12.77 | mW | 11.31 | mW | 1548.515 |
| 52 | 28.87 mW | 16.93 | mW | 1.12 | mW | 1548.915 |

•
•
•

| | | | | | | |
|---|---|---|---|---|---|---|
| 75 | 25.79 mW | 13.82 | mW | 2.56 | mW | 1558.173 |
| 76 | 30.09 mW | 17.98 | mW | 14.73 | mW | 1558.578 |
| 77 | 34.49 mW | 22.15 | mW | 12.13 | mW | 1558.983 |

•
•
•

| | | | | | | |
|---|---|---|---|---|---|---|
| 100 | 30.75 mW | 18.99 | mW | 9.75 | mW | 1568.362 |

Control device 110 selects one of channels Ch 1 to Ch 100. As shown in Table 1, when one of channels Ch 1 to Ch 25 is selected, a forward bias voltage is applied to semiconductor element 40 (first semiconductor element), and a current of 100 mA flows. A reverse bias voltage of −1 V, for example, is applied to each of semiconductor elements 42, 44 and 46 (second semiconductor element). Semiconductor element 40 emits light. The light absorptivities of semiconductor elements 42, 44, and 46 become higher than that of semiconductor element 40.

As shown in Table 2, when one of channels Ch 1 to Ch 25 is selected, an electric power of 2.5 mW is input to heater 35. Among optical waveguides 12a and 12b, optical waveguide 12a is selected as an optical path. An electric power (first value) of 2.5 mW is input to heater 36. Among optical waveguides 14a and 14b, optical waveguide 14a is selected as an optical path. The light transmittances of optical waveguides 12b and 14b are lower than those of optical waveguides 12a and 14a. No electric power is input to heater 37. The light transmittances of optical waveguides 14c and 14d are lower than those of optical waveguides 12a and 14a. Light emitted from semiconductor element 40 is propagated through optical waveguides 14a and 12a and also propagated through optical waveguide 16. Optical waveguide 14a is provided with loop mirror 20. Optical waveguide 16 is provided with loop mirror 19. The two loop mirrors, the optical waveguides and semiconductor element 40 form a laser resonator. The light is propagated through the optical waveguides and is repeatedly reflected on loop mirror 19 and loop mirror 20 to cause laser oscillation.

As shown in Table 3, when Ch 1 is selected, the electric power of heater 30 is set to 13.64 mW. The electric power of heater 32 is set to 2.12 mW. The wavelength of the light is controlled to 1528.773 nm. The electric power of heater 34 is set to 0.59 mW. The phase of the light is adjusted. When Ch 2 is selected, the electric power of heater 30 is set to 17.85 mW. The electric power of heater 32 is set to 6.21 mW. The wavelength of the light is controlled to 1529.163 nm. The electric power of heater 34 is set to 13.13 mW. When Ch 25 is selected, the electric power of heater 30 is set to 15.17 mW. The electric power of heater 32 is set to 3.57 mW. The wavelength of the light is controlled to 1538.186 nm. The electric power of heater 34 is set to 5.69 mW.

As shown in Table 1, when one of channels Ch 26 to Ch 50 is selected, a forward bias voltage is applied to semiconductor element 42 (first semiconductor element), and a current of 100 mA flows. A reverse bias voltage of −1 V, for example, is applied to each of semiconductor elements 40, 44 and 46 (second semiconductor element). Semiconductor element 42 emits light. The light absorptivities of semiconductor elements 40, 44, and 46 become higher than that of semiconductor element 42.

As shown in Table 2, when one of channels Ch 26 to Ch 50 is selected, an electric power of 2.5 mW is input to heater 35. Among optical waveguides 12a and 12b, optical waveguide 12a is selected as an optical path. An electric power of the 15 mW (second value) is input to heater 36. Among optical waveguides 14a and 14b, optical waveguide 14b is selected as an optical path. The light transmittances of optical waveguides 12b and 14a are lower than those of optical waveguides 12a and 14b. No electric power is input to heater 37. The light transmittances of optical waveguides 14c and 14d are lower than those of optical waveguides 12a and 14b.

As shown in Table 3, when Ch 26 is selected, the electric power of heater 30 is set to 19.58 mW. The electric power of heater 32 is set to 7.73 mW. The wavelength of the light is controlled to 1538.581 nm. The electric power of heater 34 is set to 3.08 mW. When Ch 27 is selected, the electric power of heater 30 is set to 23.83 mW. The electric power of heater 32 is set to 11.86 mW. The wavelength of the light is controlled to 1538.976 nm. The electric power of heater 34 is 0.47 mW. When Ch 50 is selected, the electric power of heater 30 is set to 20.08 mW. The electric power of heater 32 is set to 8.52 mW. The wavelength of the light is controlled to 1548.115 nm. The electric power of heater 34 is set to 13.92 mW.

As shown in Table 1, when one of channels Ch 51 to Ch 75 is selected, a forward bias voltage is applied to semiconductor element 44 (first semiconductor element), and a current of 100 mA flows. A reverse bias voltage of −1 V, for example, is applied to each of semiconductor elements 40, 42 and 46 (second semiconductor element). Semiconductor element 44 emits light. The light absorptivities of semiconductor elements 40, 42, and 46 become higher than that of semiconductor element 44.

As shown in Table 2, when one of channels Ch 51 to Ch 75 is selected, the electric power of 15 mW is input to heater 35. Among optical waveguides 12a and 12b, optical waveguide 12b is selected as an optical path. An electric power of 2.5 mW (first value) is input to heater 37. Among optical waveguides 14c and 14d, optical waveguide 14c is selected as an optical path. The light transmittances of optical waveguides 12a and 14d are lower than those of optical waveguides 12b and 14c. No electric power is input to heater 36. The light transmittances of optical waveguides 14a and 14b are lower than those of optical waveguides 12b and 14c.

As shown in Table 3, when Ch 51 is selected, the electric power of heater 30 is set to 24.57 mW. The electric power of heater 32 is set to 12.77 mW. The wavelength of the light is controlled to 1548.515 nm. The electric power of heater 34 is set to 11.31 mW. When Ch 52 is selected, the electric power of heater 30 is set to 28.87 mW. The electric power of heater 32 is set to 16.93 mW. The wavelength of the light is controlled to 1548.915 nm. The electric power of heater 34 is set to 1.12 mW. When Ch 75 is selected, the electric power of heater 30 is 25.79 mW. The electric power of heater 32 is set to 13.82 mW. The wavelength of the light is controlled to 1558.173 nm. The electric power of heater 34 is set to 2.56 mW.

As shown in Table 1, when one of channels Ch 76 to Ch 100 is selected, a forward bias voltage is applied to semiconductor element 46 (first semiconductor element), and a current of 100 mA flows. A reverse bias voltage of −1 V, for example, is applied to each of semiconductor elements 40, 42 and 44 (second semiconductor element). Semiconductor element 46 emits light. The light absorptivities of semiconductor elements 40, 42 and 44 become higher than that of semiconductor element 46.

As shown in Table 2, when one of channels Ch 76 to Ch 100 is selected, an electric power of 15 mW is input to heater 35. Among optical waveguides 12a and 12b, optical waveguide 12b is selected as an optical path. An electric power of 15 mW (second value) is input to heater 37. Among optical waveguides 14c and 14d, optical waveguide 14d is selected as an optical path. The light transmittances of optical waveguides 12a and 14c are lower than those of optical waveguides 12b and 14d. No electric power is input to heater 36. The light transmittances of optical waveguides 14a and 14b are lower than those of optical waveguides 12b and 14d.

As shown in Table 3, when Ch 76 is selected, the electric power of heater 30 is set to 30.09 mW. The electric power of heater 32 is 17.98 mW. The wavelength of the light is controlled to 1558.578 nm. The electric power of heater 34 is set to 14.73 mW. When Ch 77 is selected, the electric power of heater 30 is set to 34.49 mW. The electric power of heater 32 is 22.15 mW. The wavelength of the light is controlled to 1558.983 nm. The electric power of heater 34 is set to 12.13 mW. When Ch 100 is selected, the electric power of heater 30 is set to 30.75 mW. The electric power of heater 32 is 18.99 mW. The wavelength of the light is controlled to 1568.362 nm. The electric power of heater 34 is set to 9.75 mW.

Control device 110 switches channels Ch1 to Ch100 to select one of semiconductor elements 40, 42, 44, and 46 as a light-emitting element. The wavelength of light varies within a range of about 40 nm.

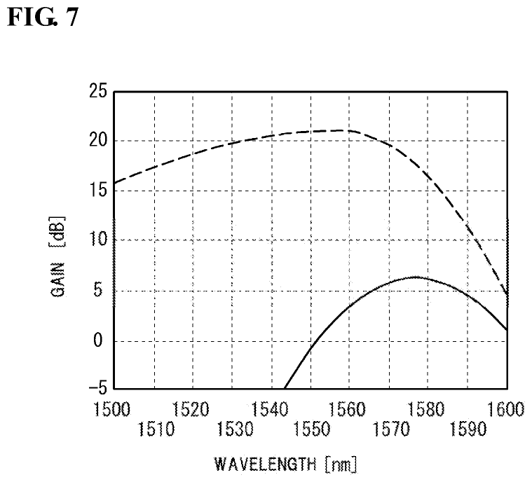

FIG. 7 is a diagram illustrating a gain of a semiconductor element. A horizontal axis represents a wavelength of light. A vertical axis represents the gain. A solid line represents an example of a semiconductor element that does not use a band filling effect. The magnitude of the gain and the wavelength dependence of the gain are comparable to those of the semiconductor element of the embodiment. When the wavelength of light emitted from one of the semiconductor elements is changed in a range of several tens of nanometers, for example, an oscillation mode may change to an unintended wavelength. For example, a wavelength of 1560 nm is set as a target oscillation wavelength. In the example indicated by the solid line in FIG. 7, the gain around a wavelength of 1580 nm is higher than the gain at a wavelength of 1560 nm. The oscillation mode may change to a wavelength around 1580 nm which is an unintended wavelength.

A dashed line represents an example of a semiconductor element using the band filling effect. By using the band filling effect, the gain of the semiconductor element is increased over a wide wavelength range. By driving one semiconductor element, the wavelength of light can be changed in a range of several tens of nanometers, for example. However, a threshold current density increases. As the threshold current density increases, the electric power consumption of the wavelength tunable laser device increases and the spectral line width increases.

According to the present embodiment, a plurality of semiconductor elements 40, 42, 44 and 46 are bonded on the optical waveguides of substrate 10 and are optically coupled to the optical waveguides. As shown in FIG. 3A, the wavelengths with which the gains of the plurality of semiconductor elements reach peaks differ from one another. Control device 110 selects an optical waveguide configured to transmit light from among optical waveguides 14a, 14b, 14c, and 14d of substrate 10. Control device 110 causes a semiconductor element bonded on the selected optical waveguide to emit light. The wavelength of light can be changed by switching between the optical waveguides and between the semiconductor elements. As shown in FIG. 3A, each one of the semiconductor elements has a high gain within a band of about 10 nm, for example. By driving one of the semiconductor elements within the high gain band thereof, mode hopping is suppressed and efficiency is improved. Since it is not necessary to use the band filling effect, an increase in threshold current density and an increase in electric power consumption are suppressed. The spectral line width of the light emitted from wavelength tunable laser device 100 is narrowed and the selectivity of the wavelength is improved.

Optical waveguide 14a is provided with heater 36. One of two optical waveguides 14a and 14b can be selected by control device 110 controlling the electric power to be input to heater 36. Optical waveguide 14c is provided with heater 37. One of two optical waveguides 14c and 14d can be selected by control device 110 controlling the electric power to be input to heater 37. By changing the electric power, the transmittance of one of the two optical waveguides is increased and the transmittance of the other one of the two optical waveguides is decreased. One optical waveguides corresponding to the semiconductor element to be driven is selected. The light emitted from the semiconductor element can be propagated through the selected optical waveguide.

By combining the selection of optical waveguide 14a by controlling heater 36 and the selection of optical waveguide 12a by controlling heater 35 with each other, the transmittance of the optical path from loop mirror 19 to loop mirror 20 becomes high. At the same time, the non-selection of optical waveguide 14b by controlling heater 36 and the non-selection of optical waveguide 12b by controlling heater 35 are combined with each other. The transmittance of the optical path from loop mirror 19 to loop mirrors 21, 22 and 23 becomes low. During optical resonance occurring between loop mirror 19 and loop mirror 20, occurrence of unnecessary optical resonance between loop mirror 19 and another loop mirror is suppressed. Alternatively, the optical waveguide is selected by controlling heater 36 and heater 35 so that optical resonance occurs between any one of loop mirrors 21, 22, and 23 and loop mirror 19. At this time, the optical waveguides between the remaining loop mirrors and loop mirror 19 are not selected as an optical path. The occurrence of unnecessary optical resonance is suppressed. The singleness of wavelength of the wavelength tunable laser device is improved.

As shown in FIG. 3B, the transmittance of the optical waveguide changes periodically with the electric power to be input to the heater. By setting the electric power to 2.5 mW, one of the optical waveguides can be selected. By setting the electric power to 15 mW, the other one of the optical waveguides can be selected. The two optical waveguides can be easily switched by controlling the electric power to be input to one of the heaters. Other than the heater, an element functioning as a switch for switching optical waveguides may be used.

Optical waveguide 12a is optically coupled to optical waveguides 14a and 14b. Optical waveguide 12b is optically coupled to optical waveguides 14c and 14d. When semiconductor element 40 or 42 emits light, one of optical waveguides 14a and 14b, and optical waveguide 12a are selected as optical waveguides configured to transmit the light. The light emitted from semiconductor element 40 or the light emitted from semiconductor element 42 is propagated through optical waveguide 12a. When semiconductor element 44 or 46 emits light, one of optical waveguides 14c and 14d, and optical waveguide 12b are selected as optical waveguides configured to transmit the light. The light emitted from semiconductor element 44 or the light emitted from semiconductor element 46 is propagated through optical waveguide 12b. Optical waveguides 12a and 12b are optically coupled to optical waveguide 16. The light emitted from the semiconductor element is propagated through optical waveguide 16. The light can be propagated through the optical waveguide and emitted from the light emitting port (end portion 16d).

Two ring resonators 17 and 18 are optically coupled to optical waveguide 16. Ring resonators 17 and 18 can be used to control the wavelength of the light. Heaters 30 and 32 are used to control the resonant wavelengths of ring resonators 17 and 18. The wavelength with which the peaks of the transmittances of two ring resonators 17 and 18 coincide with each other is an oscillation wavelength. By controlling the resonant wavelengths of the two ring resonators, the oscillation wavelength can be changed in a range of about 40 nm as shown in Table 3, for example. The number of ring resonators may be two or more.

Wavelength tunable laser device 100 is provided with loop mirrors 19, 20, 21, 22 and 23. Loop mirror 19 faces and is optically coupled to an end portion of one of semiconductor elements 40, 42, 44 and 46. Loop mirrors 20, 21, 22, and 23 are disposed corresponding to semiconductor elements 40, 42, 44, and 46, respectively, and are located opposite to loop mirror 19 across the semiconductor elements on the optical path. Loop mirror 19 and loop mirrors 20, 21, 22 and 23 form a laser resonator.

By integrating a plurality of semiconductor elements, a plurality of loop mirrors, and a plurality of ring resonators, wavelength tunable laser device 100 can be miniaturized. Wavelength tunable laser device 100 may be provided with optical elements other than the loop mirror and the ring resonator. The arrangement and number of optical waveguides, ring resonators, loop mirrors, and semiconductor elements are not limited to the example shown in FIG. 1.

When one of the semiconductor elements emits light, the light absorptivities of the other semiconductor elements are increased. Since the other semiconductor elements absorb light, unnecessary reflected light can be reduced. As shown in FIG. 2B, each of the semiconductor elements include n-type cladding layer 60, active layer 62, p-type cladding layer 64, and contact layer 66. When a forward bias voltage is applied to one of the semiconductor elements, the one of the semiconductor elements generates light. The other three semiconductor elements easily absorb light when reverse bias voltages are applied to the three semiconductor elements. By controlling the bias voltages applied to the semiconductor elements, the semiconductor elements can be switched from a state of light generation to a state of light absorption, and vice versa.

Application of reverse bias voltages to the semiconductor elements which do not emit light and non-selection of the optical waveguides between the loop mirrors which do not contribute to optical resonance by controlling the heaters are combined with each other. The transmittances between the semiconductor elements that do not emit light and loop mirror 19 become low. The reflected light of loop mirror 19 entering the semiconductor elements which do not emit light can be reduced. Reverse bias currents flowing through semiconductor elements to which the reverse bias voltages are applied are minimized. Unnecessary currents flowing through the semiconductor elements that do not emit light can be reduced. Since the unnecessary reflected light is reduced, the singleness of wavelength of the emitted light is improved.

The n-type semiconductor layer, active layer 62, and the p-type semiconductor layer may be stacked in this order on substrate 10. The p-type semiconductor layer, active layer 62, and the n-type semiconductor layer may be stacked in this order on substrate 10.

The wavelength dependence of the gain is determined by a composition of active layer 62. By changing the composition of active layer 62 for each semiconductor element, the wavelength with which the gain reaches a peak is changed as shown in FIG. 3A. The difference between the wavelengths with which the gains reach peaks may be 5 nm or more, 10 nm or more, 15 nm or more, or 20 nm or more. In the example of FIG. 3A, the difference in peak wavelengths is 10 nm or more. Each of semiconductor elements is driven in a band of, for example, about 10 nm. Using the four semiconductor elements, light can be emitted in a range of 40 nm from 1530 nm to 1570 nm. The band of the C-band (1529 nm to 1568 nm) is approximately covered. The wavelength range in which one semiconductor element is driven may be 10 nm, less than 10 nm, or more than 10 nm.

By increasing the number of semiconductor elements, the wavelength band that can be covered is widened. The number of semiconductor elements bonded on substrate 10 is two or more, and may be four or more. The number of optical waveguides is changed according to the number of semiconductor elements. One semiconductor element is bonded to one optical waveguide.

As wavelength tunable laser device 100, an example in which a plurality of semiconductor elements are bonded on a plurality of optical waveguides has been described. Each of the semiconductor elements may be a semiconductor laser chip formed on a substrate independent of SOI substrate 50 and not bonded on an optical waveguide. The plurality of semiconductor laser chips have gain peak wavelengths that differ from one another, as shown in FIG. 3A. The semiconductor laser chips may be optically coupled to optical waveguides using a lens.

The functions described above can be achieved by a computer. In this case, a program describing the processing contents of the functions to be processed by a processing apparatus is provided. By executing the program on the computer, the processing functions are achieved on the computer. The program describing the processing contents may be recorded in a computer-readable storage medium (excluding a carrier wave).

When the program is distributed, for example, the program is sold in a form of a portable storage medium such as a digital versatile disc (DVD) or a compact disc read only memory (CD-ROM) on which the program is recorded. It is also possible to store the program in a storage device of a server computer and transfer the program from the server computer to another computer via a network.

The computer that executes the program stores, for example, the program recorded in the portable storage medium or the program transferred from the server computer in its own storage device. Then, the computer reads the program from its own storage device and executes processing in accordance with the program. The computer may read the program directly from the portable storage medium and execute processing in accordance with the program. Further, each time a program is transferred from the server computer, the computer can sequentially execute processing in accordance with the received program.

Although the embodiments of the present disclosure have been described in detail above, the present disclosure is not limited to the specific embodiments, and various modifications and changes can be made within the scope of the gist of the present disclosure described in the claims.

What is claimed is:

1. A method of controlling a wavelength tunable laser device including a substrate and a plurality of semiconductor elements,
wherein a plurality of first optical waveguides are provided in the substrate,
wherein the plurality of semiconductor elements are formed of a III-V group compound semiconductor, have optical gains, and are optically coupled to the plurality of first optical waveguides of the substrate,
wherein wavelengths with which the optical gains of the plurality of semiconductor elements reach peaks differ from one another, and
wherein the method comprises:
selecting a first optical waveguide configured to transmit light from among the plurality of first optical waveguides; and
causing light to be emitted from a first semiconductor element that is a semiconductor element optically coupled to the selected first optical waveguide among the plurality of semiconductor elements.

2. The method of controlling the wavelength tunable laser device according to claim 1,
wherein a heater is provided over one of two of the first optical waveguides, and
wherein the selecting includes selecting one of the two first optical waveguides by controlling an electric power to be input to the heater.

3. The method of controlling the wavelength tunable laser device according to claim 2, wherein the selecting includes selecting one of the two first optical waveguides by setting an electric power to be input to the heater to a first value, and selecting the other one of the two first optical waveguides by setting the electric power to a second value.

4. The method of controlling the wavelength tunable laser device according to claim 1,
wherein the substrate includes a second optical waveguide optically coupled to the plurality of first optical waveguides,
wherein the second optical waveguide is branched into two,
wherein one of the first optical waveguides is optically coupled to one of the two branched second optical waveguides, and another one of the first optical waveguides is optically coupled to the other one of the two branched second optical waveguides,
wherein the method comprises selecting a second optical waveguide configured to transmit light from among the two branched second optical waveguides, and
wherein, in the selecting the second optical waveguide configured to transmit light, a second optical waveguide optically coupled to the selected first optical waveguide is selected.

5. The method of controlling the wavelength tunable laser device according to claim 4,
wherein the wavelength tunable laser device includes a plurality of ring resonators optically coupled to the second optical waveguide, and
wherein the method comprises controlling resonant wavelengths of the plurality of ring resonators.

6. The method of controlling the wavelength tunable laser device according to claim 1, comprising increasing a light absorptivity of a second semiconductor element that is a semiconductor element other than the first semiconductor element among the plurality of semiconductor elements to be higher than the light absorptivity before the causing the light to be emitted.

7. The method of controlling the wavelength tunable laser device according to claim 6,
wherein the causing the light to be emitted from the first semiconductor element includes applying a forward bias voltage to the first semiconductor element, and
wherein the increasing the light absorptivity of the second semiconductor element includes applying a reverse bias voltage to the second semiconductor element.

8. The method of controlling the wavelength tunable laser device according to claim 7, wherein the increasing the light absorptivity of the second semiconductor element includes detecting a reverse bias current flowing through the second semiconductor element, and controlling the reverse bias current to a minimum value.

9. A non-transitory storage medium storing a control program executable by a computer for controlling a wavelength tunable laser device including a substrate and a plurality of semiconductor elements,
wherein a plurality of first optical waveguides are provided in the substrate,
wherein the plurality of semiconductor elements are formed of a III-V group compound semiconductor, have optical gains, and are optically coupled to the plurality of first optical waveguides of the substrate,
wherein wavelengths with which the optical gains of the plurality of semiconductor elements reach peaks differ from one another, and
wherein the control program causes a computer to function as:
a selection controller configured to select a first optical waveguide configured to transmit light from among the plurality of first optical waveguides; and
an emission controller configured to cause light to be emitted from a semiconductor element optically coupled to the selected first optical waveguide among the plurality of semiconductor elements.

10. A control device of a wavelength tunable laser device including a substrate and a plurality of semiconductor elements,
wherein a plurality of first optical waveguides are provided in the substrate,
wherein the plurality of semiconductor elements are formed of a III-V group compound semiconductor, have optical gains, and are optically coupled to the plurality of first optical waveguides of the substrate,
wherein wavelengths with which the optical gains of the plurality of semiconductor elements reach peaks differ from one another, and
wherein the control device comprises:
a selection controller configured to select a first optical waveguide configured to transmit light from among the plurality of first optical waveguides; and
an emission controller configured to cause light to be emitted from a semiconductor element optically coupled to the selected first optical waveguide among the plurality of semiconductor elements.
